(19) United States
(12) Patent Application Publication
(10) Pub. No.: US 2025/0081589 A1
(43) Pub. Date: Mar. 6, 2025

(54) SEMICONDUCTOR DEVICE AND METHOD OF MANUFACTURING SEMICONDUCTOR DEVICE

(71) Applicant: SUMITOMO ELECTRIC INDUSTRIES, LTD., Osaka (JP)

(72) Inventor: Masaya OKADA, Osaka (JP)

(21) Appl. No.: 18/805,929

(22) Filed: Aug. 15, 2024

(30) Foreign Application Priority Data
Aug. 31, 2023 (JP) 2023-141124

(51) Int. Cl. H01L 29/51; H01L 21/28; H01L 29/20; H01L 29/66; H01L 29/778

(52) U.S. Cl. CPC H10D 64/693; H01L 21/28264; H10D 30/015; H10D 30/475; H10D 62/8503

(57) ABSTRACT

A semiconductor device includes a nitride semiconductor layer, a dielectric oxynitride film provided on the nitride semiconductor layer and having a first surface facing the nitride semiconductor layer, and a gate electrode provided on the dielectric oxynitride film. A surface of the nitride semiconductor layer facing the dielectric oxynitride film has a nitrogen polarity.

### CROSS-REFERENCE TO RELATED APPLICATIONS

This application is based on and claims priority to Japanese Patent Application No. 2023-141124, filed on Aug. 31, 2023, the entire contents of which are incorporated herein by reference.

### TECHNICAL FIELD

The present disclosure relates to a semiconductor device and a method of manufacturing a semiconductor device.

### BACKGROUND

A high electron mobility transistor (HEMT) in which a channel layer is formed on a barrier layer has been proposed. Further, as a material of a gate insulating film, hafnium silicate having a high relative dielectric constant is known. For example, see Japanese Laid-open Patent Publication No. 2009-506537, Japanese Laid-open Patent Publication No. 05-223855, and International Publication Pamphlet No. WO2005/119787.

### SUMMARY

A semiconductor device according to the present disclosure includes a nitride semiconductor layer, a dielectric oxynitride film provided on the nitride semiconductor layer and having a first surface facing the nitride semiconductor layer, and a gate electrode provided on the dielectric oxynitride film, wherein a surface of the nitride semiconductor layer facing the dielectric oxynitride film has a nitrogen polarity.

### BRIEF DESCRIPTION OF THE DRAWINGS

FIG. 1 is a cross-sectional view illustrating a semiconductor device according to an embodiment;

FIG. 2 is a cross-sectional view illustrating the configuration of a dielectric oxynitride film;

FIG. 3 is a diagram illustrating the trend of the bonding strength measured by X-ray photoelectron spectroscopy;

FIG. 4 is a cross-sectional view (part 1) illustrating a method of manufacturing a semiconductor device according to an embodiment;

FIG. 5 is a cross-sectional view (part 2) illustrating the method of manufacturing the semiconductor device according to the embodiment;

FIG. 6 is a cross-sectional view (part 3) illustrating the method of manufacturing the semiconductor device according to the embodiment;

FIG. 7 is a cross-sectional view (part 4) illustrating the method of manufacturing the semiconductor device according to the embodiment;

FIG. 8 is a cross-sectional view (part 5) illustrating the method of manufacturing the semiconductor device according to the embodiment;

FIG. 9 is a cross-sectional view (part 6) illustrating the method of manufacturing the semiconductor device according to the embodiment; and

FIG. 10 is a cross-sectional view (part 7) illustrating the method of manufacturing the semiconductor device according to the embodiment.

### DETAILED DESCRIPTION

In recent years, there has been an increasing demand to reduce gate leakage.

It is an object of the present disclosure to provide a semiconductor device that can reduce gate leakage, and a method of manufacturing the semiconductor device.

According to the present disclosure, gate leakage can be reduced.

### Description of Embodiments of Present Disclosure

First, embodiments of the present disclosure will be listed and described.

[1] A semiconductor device according to one aspect of the present disclosure includes: a nitride semiconductor layer; a dielectric oxynitride film provided on the nitride semiconductor layer and having a first surface facing the nitride semiconductor layer; and a gate electrode provided on the dielectric oxynitride film, wherein a surface of the nitride semiconductor layer facing the dielectric oxynitride film has a nitrogen polarity.

The surface of the nitride semiconductor layer facing the dielectric oxynitride film has the nitrogen polarity, and thus a reduction in resistance is more likely to be achieved. Further, the dielectric oxynitride film functions as a gate insulating film. The dielectric oxynitride film has a higher insulating property and a higher breakdown voltage than those of the dielectric oxide film, and thus gate leakage can be reduced.

[2] In [1], a first concentration of nitrogen atoms at a first point in the dielectric oxynitride film may be higher than a second concentration of nitrogen atoms at a second point in the dielectric oxynitride film, the first point being spaced apart from the first surface by a first distance, and the second point being spaced apart from the first surface by a second distance that is longer than the first distance. In this case, the affinity between the dielectric oxynitride film and the nitride semiconductor layer is high, and an interface state formed at the interface between the dielectric oxynitride film and the nitride semiconductor layer is reduced, and thus current collapse is likely to be suppressed.

[3] In [2], a concentration of nitrogen atoms in the dielectric oxynitride film may continuously change with respect to a distance from the first surface. In this case, the improvement of the breakdown voltage of the dielectric oxynitride film is facilitated.

[4] In any one of [1] to [3], the dielectric oxynitride film may include at least one selected from a group consisting of hafnium, lanthanum, and zirconium. In this case, the dielectric oxynitride film is more likely to have a high relative dielectric constant.

[5] In [4], the dielectric oxynitride film may include at least one selected from a group consisting of silicon and aluminum. In this case, the dielectric oxynitride film is more likely to have a high relative dielectric constant.

[6] A method of manufacturing a semiconductor device according to another aspect of the present disclosure includes: forming, on a nitride semiconductor layer, a dielectric oxide film having a higher relative dielectric constant than a relative dielectric constant of silicon dioxide; forming a dielectric oxynitride film by nitriding the dielectric oxide film; and forming a gate electrode on the dielectric oxynitride film, wherein a surface of the nitride semiconductor layer facing the dielectric oxide film has a nitrogen polarity.

The surface of the nitride semiconductor layer facing the dielectric oxide film has the nitrogen polarity, and thus a reduction in the resistance of the semiconductor device is more likely to be achieved. Further, gate leakage can be reduced.

### Details of Embodiments of Present Disclosure

The embodiments of the present disclosure will be described in detail below; however, the present disclosure is not limited thereto. In the present specification and the drawings, components having substantially the same functional configurations are denoted by the same reference numerals and a redundant description thereof may be omitted. In the present disclosure, the phrase “in a plan view” means viewing an object from above.

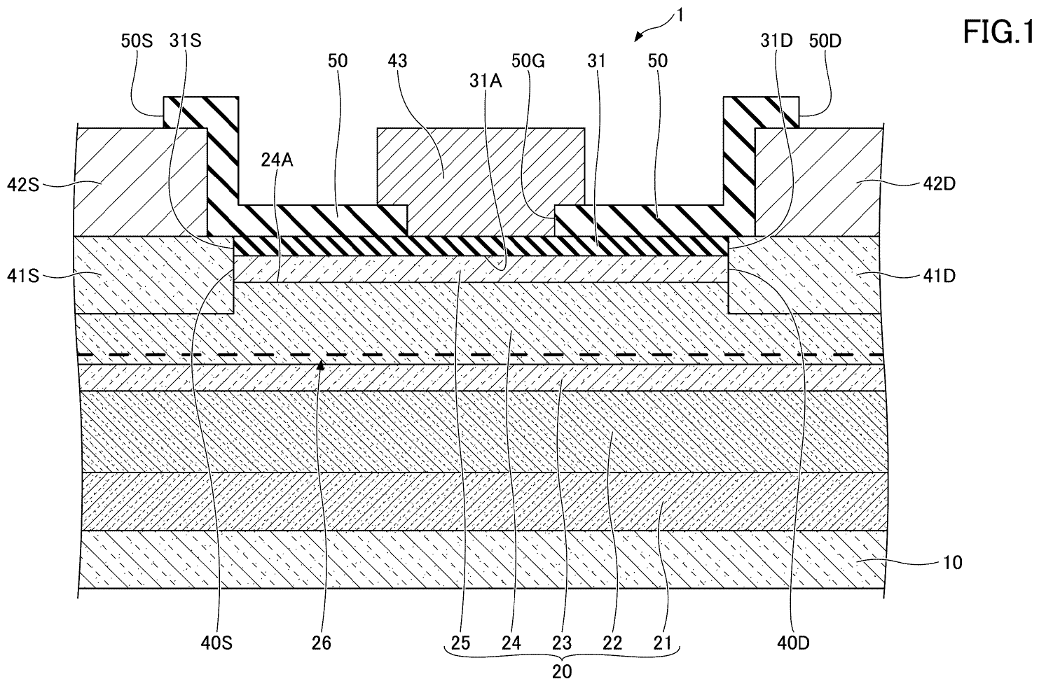

The embodiments relate to a semiconductor device including a GaN-based high electron mobility transistor (HEMT). FIG. 1 is a cross-sectional view illustrating a semiconductor device according to an embodiment.

As illustrated in FIG. 1, a semiconductor device 1 according to the embodiment mainly includes a growth substrate 10, a nitride semiconductor layer 20, a dielectric oxynitride film 31, a passivation film 50, a regrowth layer 41S, a regrowth layer 41D, a gate electrode 43, a source electrode 42S, and a drain electrode 42D.

The growth substrate 10 is, for example, a semi-insulating silicon carbide (SiC) substrate. In a case where the growth substrate 10 is an SiC substrate, the upper surface of the growth substrate 10 is a carbon (C)-polar surface. In a case where the surface of the growth substrate 10 is a C-polar surface, the nitride semiconductor layer 20 can be crystal-grown by using a nitrogen (N)-polar surface as a growth surface.

The nitride semiconductor layer 20 includes a buffer layer 21, a barrier layer 22, a spacer layer 23, a channel layer 24, and a cap layer 25.

The buffer layer 21 is located on the growth substrate 10. The buffer layer 21 is, for example, an aluminum nitride (AlN) layer. The thickness of the AlN layer is, for example, 1 nm or more and 2,000 nm or less. The buffer layer 21 may include an AlN layer, and a GaN layer or an aluminum gallium nitride (AlGaN) layer on the AlN layer.

The barrier layer 22 is located on the buffer layer 21. The barrier layer 22 is, for example, an AlGaN layer. The band gap of the barrier layer 22 is larger than the band gap of the channel layer 24. The thickness of the barrier layer 22 is, for example, 1 nm or more and 50 nm or less. The composition of the barrier layer 22 is, for example, Al_{y}Ga_{1-y}N (0.15≤Y≤0.55). The conductivity type of the barrier layer 22 is, for example, an n-type or an undoped type (i-type). Instead of the AlGaN layer, a scandium aluminum nitride (ScAlN) layer, an indium aluminum nitride (InAlN) layer, or an indium aluminum gallium nitride (InAlGaN) layer may be used.

The spacer layer 23 is located on the barrier layer 22. The spacer layer 23 is, for example, an AlN layer. The thickness of the spacer layer 23 is, for example, in a range of 0.2 nm or more and 5 nm or less.

The channel layer 24 is located on the spacer layer 23. The channel layer 24 is, for example, a GaN layer. The band gap of the channel layer 24 is smaller than the band gap of the barrier layer 22. The thickness of the channel layer 24 is, for example, 1 nm or more and 50 nm or less. A strain is generated between the channel layer 24 and a stack of the barrier layer 22 and spacer layer 23 due to a difference in their lattice constants, and the strain induces a piezoelectric charge at the interface therebetween. As a result, a two-dimensional electron gas (2DEG) is generated inside the channel layer 24 in the vicinity of the surface of the channel layer 24 facing the barrier layer 22, thereby forming a channel region 26. The conductivity type of the channel layer 24 is, for example, an n-type or an undoped type (i-type).

The cap layer 25 is located on the channel layer 24. The cap layer 25 is, for example, an AlGaN layer. The thickness of the cap layer 25 is, for example, 0.1 nm or more and 10 nm or less.

On the C-polar surface of the SiC

substrate, the buffer layer 21, the barrier layer 22, the spacer layer 23, the channel layer 24, the cap layer 25 are crystal-grown by using N-polar surfaces as growth surfaces. Therefore, each of the upper surfaces of the buffer layer 21, the barrier layer 22, the spacer layer 23, the channel layer 24, and the cap layer 25 has an N-polarity, and each of the lower surfaces of the buffer layer 21, the barrier layer 22, the spacer layer 23, the channel layer 24, and the cap layer 25 has a gallium (Ga)-polarity.

A recess 40S for a source and a recess 40D for a drain are formed in the nitride semiconductor layer 20. The bottom of the recess 40S and the bottom of the recess 40D are located closer to the lower surface of the nitride semiconductor layer 20 than an upper surface 24A of the channel layer 24 is. That is, the recess 40S and the recess 40D are formed so as to be deeper than the upper surface 24A of the channel layer 24. The bottom of the recess 40S and the bottom of the recess 40D may be located in the channel layer 24, in the spacer layer 23, or in the barrier layer 22.

The dielectric oxynitride film 31 is located on the nitride semiconductor layer 20. The dielectric oxynitride film 31 contacts the upper surface of the nitride semiconductor layer 20. The relative dielectric constant of the dielectric oxynitride film 31 is higher than the relative dielectric constant of silicon dioxide (SiO₂). The dielectric oxynitride film 31 is a high dielectric constant film. The dielectric oxynitride film 31 may include at least one selected from the group consisting of hafnium (Hf), lanthanum (La), and zirconium (Zr). Further, the dielectric oxynitride film 31 may include at least one selected from the group consisting of silicon (Si) and aluminum (Al). For example, the dielectric oxynitride film 31 is a hafnium silicon oxynitride (HfSiON) film or a hafnium aluminum oxynitride (HfAlON) film. The thickness of the dielectric oxynitride film 31 is, for example, 1 nm or more and 30 nm or less. An opening 31S for the source and an opening 31D for the drain are formed in the dielectric oxynitride film 31. The opening 31S leads to the recess 40S, and the opening 31D leads to the recess 40D. The regrowth layer 41S is located on the

channel layer 24, the spacer layer 23, or the barrier layer 22 in the recess 40S. The regrowth layer 41D is located on the channel layer 24, the spacer layer 23, or the barrier layer 22 in the recess 40D. The regrowth layer 41S and the regrowth layer 41D are, for example, n-type GaN layers. The regrowth layer 41S and the regrowth layer 41D contain germanium (Ge) or Si as an n-type impurity. The electrical resistance of each of the regrowth layer 41S and the regrowth layer 41D is lower than the electrical resistance of the channel layer 24. For example, each of the regrowth layer 41S and the regrowth layer 41D is formed by regrowth of an n-type GaN layer after the recess 40S and the recess 40D are formed in the nitride semiconductor layer 20.

The source electrode 42S is located on the regrowth layer 41S, and the drain electrode 42D is located on the regrowth layer 41D. The source electrode 42S contacts the regrowth layer 41S, and the drain electrode 42D contacts the regrowth layer 41D. The source electrode 42S is in ohmic contact with the regrowth layer 41S, and the drain electrode 42D is in ohmic contact with the regrowth layer 41D.

The passivation film 50 covers the dielectric oxynitride film 31, the regrowth layer 41S, the regrowth layer 41D, the source electrode 42S, and the drain electrode 42D. The passivation film 50 is, for example, a silicon nitride (SiN) film. The passivation film 50 has a thickness of, for example, 5 nm or more and 100 nm or less in a portion on the dielectric oxynitride film 31 where the passivation film 50 has a uniform thickness. An opening 50S for the source, an opening 50D for the drain, and an opening 50G for a gate are formed in the passivation film 50. A portion of the source electrode 42S is exposed through the opening 50S, and a portion of the source electrode 42S is exposed through the opening 50D. The opening 50G is located between the opening 50S and the opening 50D in a plan view. A portion of the dielectric oxynitride film 31 is exposed through the opening 50G.

The gate electrode 43 is located between the source electrode 42S and the drain electrode 42D in a plan view. The gate electrode 43 is located on the passivation film 50 and the dielectric oxynitride film 31, and contacts the dielectric oxynitride film 31 through the opening 50G.

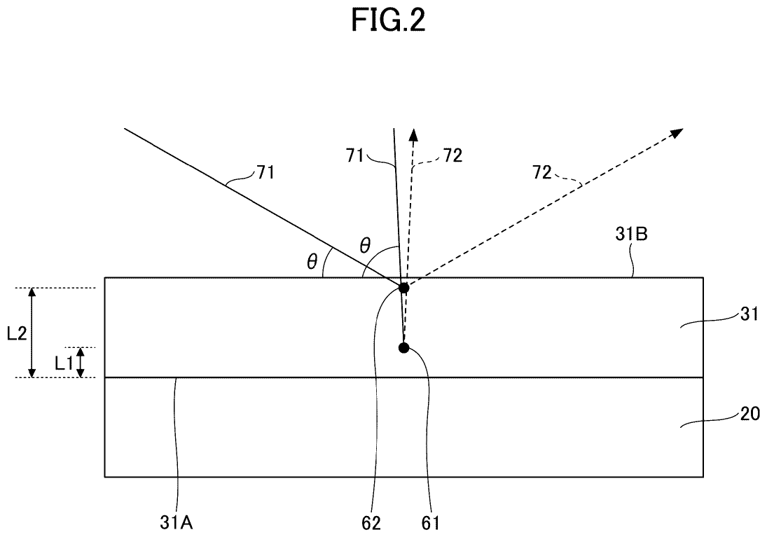

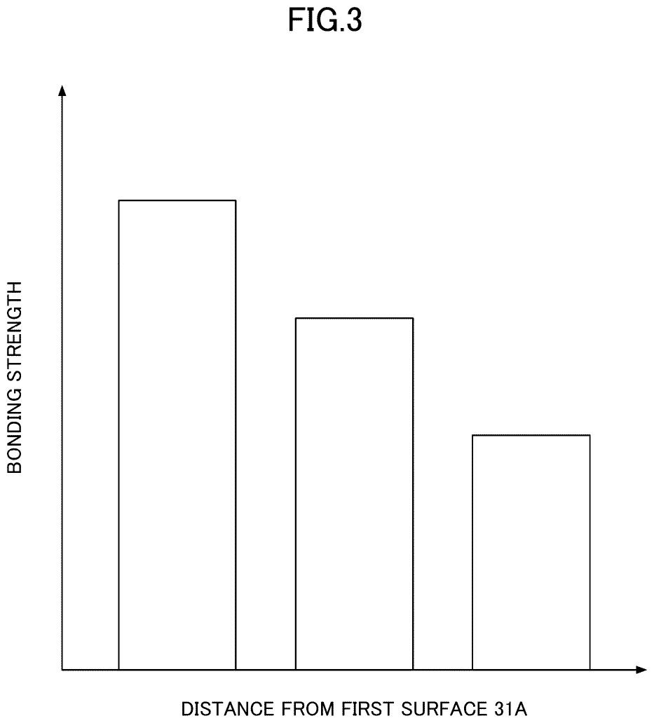

The dielectric oxynitride film 31 will be further described. FIG. 2 is a cross-sectional view illustrating the configuration of the dielectric oxynitride film 31. FIG. 3 is a diagram illustrating the trend of the bonding strength measured by X-ray photoelectron spectroscopy (XPS).

In the present embodiment, the dielectric

oxynitride film 31 has a first surface 31A facing the nitride semiconductor layer 20. A first concentration of N atoms at a first point 61 in the dielectric oxynitride film 31 is higher than a second concentration of N atoms at a second point 62 in the dielectric oxynitride film 31. The first point 61 is spaced apart from the first surface 31A by a first distance L1, and the second point 62 is spaced apart from the first surface 31A by a second distance L2 that is longer than the first distance L1. In a case where the dielectric oxynitride film 31 is a HfSiON film containing Hf as a transition metal element, the level of the concentration of N atoms in the dielectric oxynitride film 31 can be specified from the level of the bonding strength between Hf atoms and N atoms measured by XPS. That is, the higher the bonding strength between Hf atoms and N atoms measured by XPS, the higher the concentration of N atoms in the dielectric oxynitride film 31.

In the measurement of the bonding strength by XPS, a second surface 31B of the dielectric oxynitride film 31 opposite to the first surface 31A is irradiated with an X-ray 71 as illustrated in FIG. 2. In this case, as an angle (angle θ) between the second surface 31B and the irradiation direction of the X-ray 71 increases, the X-ray 71 reaches a deeper position of the dielectric oxynitride film 31. Photoelectrons 72 emitted at a point at which the X-ray 71 has reached are detected outside the dielectric oxynitride film 31. Therefore, by changing the angle θ, the bonding strength can be measured at points whose distances from the first surface 31A are different. In the present embodiment, when the bonding strength between Hf atoms and N atoms in the dielectric oxynitride film 31 is measured, the bonding strength at the first point 61 is higher than the bonding strength at the second point 62.

For example, if the thickness of the dielectric oxynitride film 31 is 10 nm, and the angle θ is set to 85°, the bonding strength at a point located at a distance of approximately 2 nm or more and 3 nm or less from the first surface 31A is obtained. If the angle θ is set to 45°, the bonding strength at a point located at a distance of approximately 5 nm or more and 6 nm or less from the first surface 31A is obtained. If the angle θ is set to 30°, the bonding strength at a point located at a distance of approximately 8 nm or more and 9 nm or less from the first surface 31A is obtained. As illustrated in FIG. 3, the larger the angle θ is, the higher the bonding strength between Hf atoms and N atoms is.

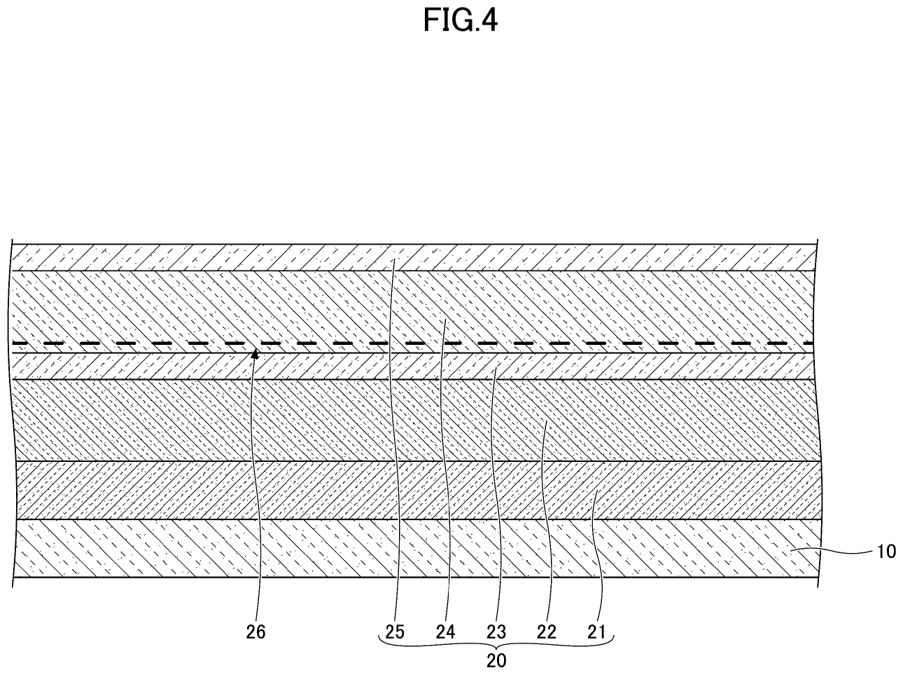

Next, a method of manufacturing the semiconductor device 1 according to the embodiment will be described. FIG. 4 to FIG. 10 are cross-sectional views illustrating the method of manufacturing the semiconductor device 1 according to the embodiment.

First, as illustrated in FIG. 4, a nitride semiconductor layer 20 is formed on a growth substrate 10 by, for example, a metal organic chemical vapor deposition (MOCVD) method. In the formation of the nitride semiconductor layer 20, a buffer layer 21, a barrier layer 22, a spacer layer 23, a channel layer 24, and a cap layer 25 are sequentially formed.

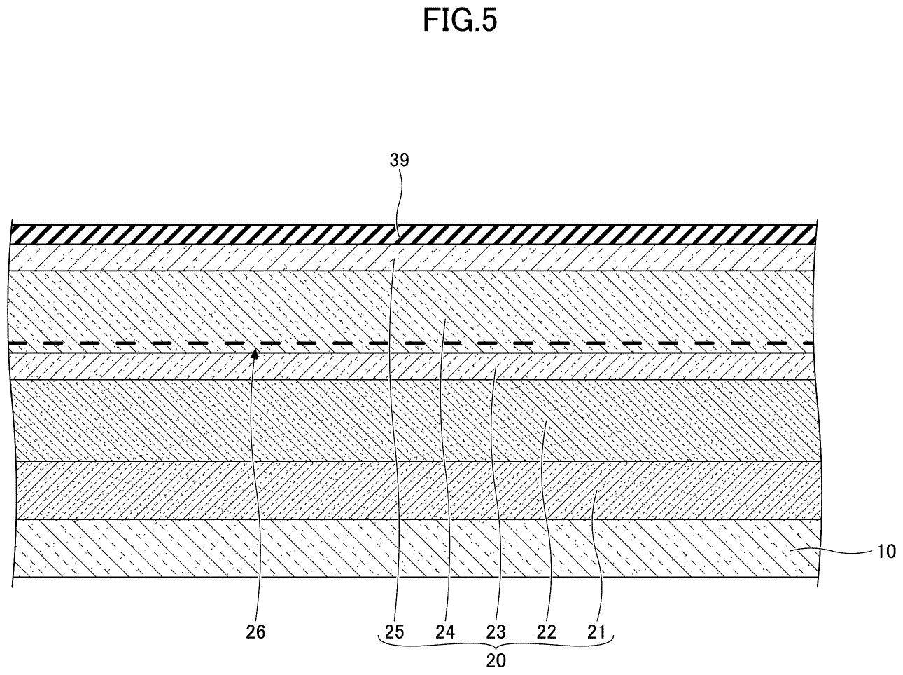

Next, as illustrated in FIG. 5, a dielectric oxide film 39 is formed on the nitride semiconductor layer 20. The dielectric oxide film 39 can be formed by, for example, an atomic layer deposition (ALD) method. The dielectric oxide film 39 contacts the upper surface of the nitride semiconductor layer 20. The relative dielectric constant of the dielectric oxide film 39 is higher than the relative dielectric constant of silicon dioxide (SiO₂). The dielectric oxide film 39 is a high dielectric constant film. The dielectric oxide film 39 may include at least one selected from the group consisting of Hf, La, and Zr. Further, the dielectric oxide film 39 may include at least one selected from the group consisting of Si and Al. For example, the dielectric oxide film 39 is a hafnium silicate (HfSiOₓ) film or a hafnium aluminate (HfAlOₓ) film. The thickness of the dielectric oxide film 39 is, for example, 1 nm or more and 30 nm or less.

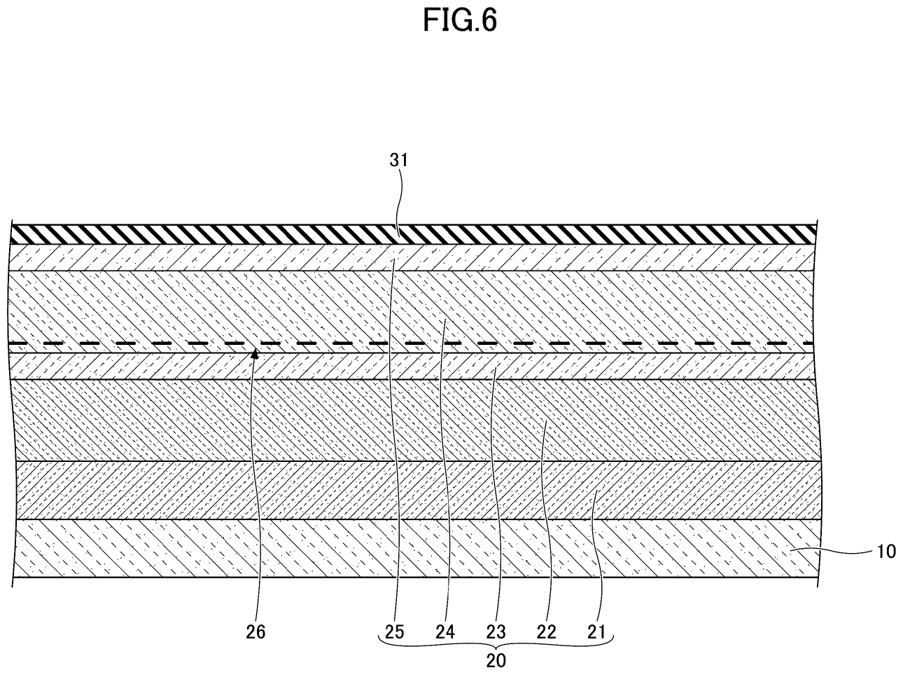

Next, as illustrated in FIG. 6, a dielectric oxynitride film 31 is formed by nitriding the dielectric oxide film 39. The dielectric oxide film 39 is nitrided in, for example, a chamber of a deposition apparatus such as a CVD apparatus. As an N source for nitriding the dielectric oxide film 39, N atoms generated by thermally decomposing ammonia (NH₃) are used, for example. When the dielectric oxide film 39 is nitrided, the dielectric oxide film 39 is also reduced.

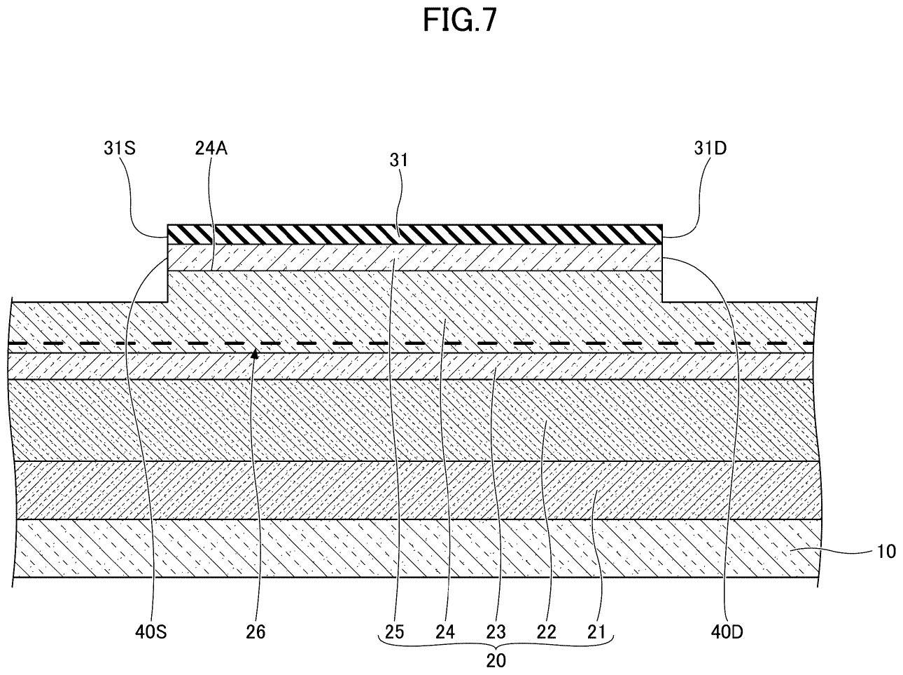

Next, as illustrated in FIG. 7, an opening 31S for a source and an opening 31D for a drain are formed in the dielectric oxynitride film 31, and a recess 40S for the source and a recess 40D for the drain are formed in the nitride semiconductor layer 20. The bottom of the recess 40S and the bottom of the recess 40D may be located closer to the lower surface of the nitride semiconductor layer 20 than an upper surface 24A of the channel layer 24 is. That is, the recess 40S and the recess 40D may be formed so as to be deeper than the upper surface 24A of the channel layer 24. The bottom of the recess 40S and the bottom of the recess 40D may be located in the channel layer 24, in the spacer layer 23, or in the barrier layer 22.

The opening 31S, the opening 31D, the recess 40S, and the recess 40D can be formed by, for example, reactive ion etching (RIE) using a mask (not illustrated). For example, in the formation of the opening 31S, the opening 31D, the recess 40S, and the recess 40D, a chlorine (Cl)-based gas is used as a reactive gas.

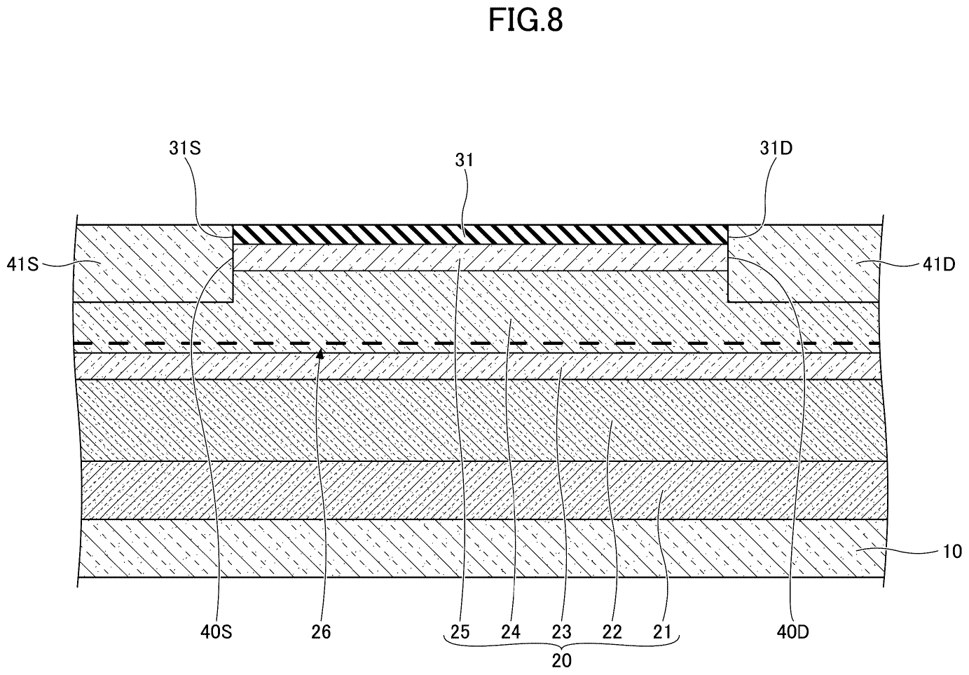

Next, as illustrated in FIG. 8, a regrowth layer 41S is formed on the channel layer 24, the spacer layer 23, or the barrier layer 22 in the recess 40S, and a regrowth layer 41D is formed on the channel layer 24, the spacer layer 23, or the barrier layer 22 in the recess 40D. The regrowth layer 41S and the regrowth layer 41D can be formed by, for example, a physical vapor deposition (PVD) method such as a vapor deposition method, a sputtering method, or a molecular beam epitaxy (MBE) method.

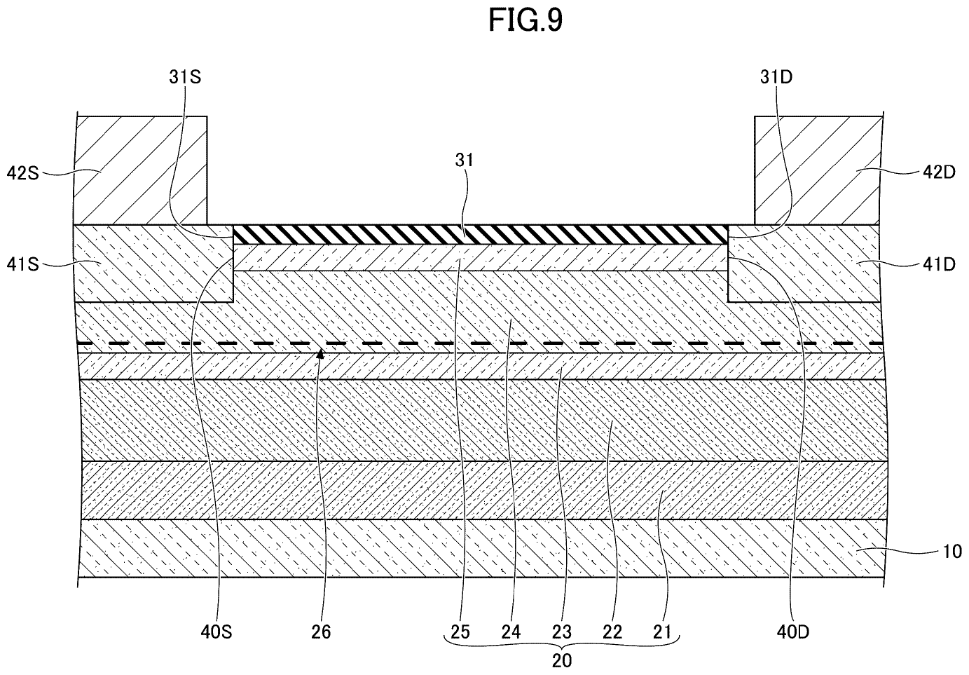

Next, as illustrated in FIG. 9, a source electrode 42S is formed on the regrowth layer 41S, and a drain electrode 42D is formed on the regrowth layer 41D. In the formation of the source electrode 42S and the drain electrode 42D, first, a metal layer (not illustrated) constituting the source electrode 42S and the drain electrode 42D is formed. In the formation of the metal layer, for example, the metal layer is formed by using a growth mask (not illustrated) having openings in regions where the source electrode 42S and the drain electrode 42D are to be formed, and then the growth mask is removed together with the metal layer (not illustrated) formed on the growth mask. That is, lift-off is performed.

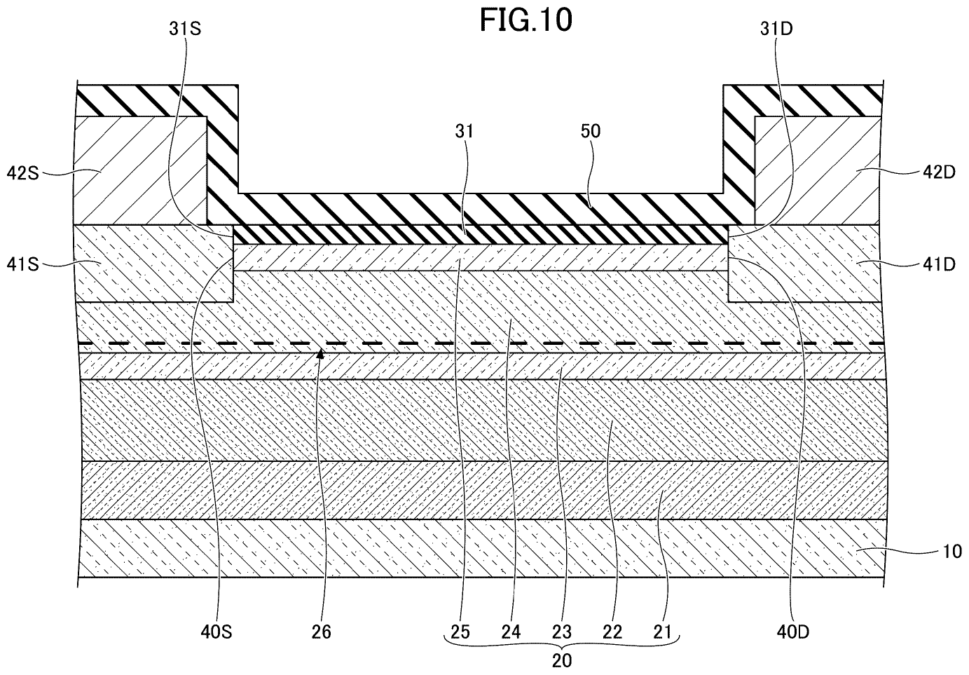

Next, as illustrated in FIG. 10, a passivation film 50 is formed on the dielectric oxynitride film 31, the regrowth layer 41S, the regrowth layer 41D, the source electrode 42S, and the drain electrode 42D. The passivation film 50 covers the dielectric oxynitride film 31, the regrowth layer 41S, the regrowth layer 41D, the source electrode 42S, and the drain electrode 42D.

Next, an opening 50G for a gate is formed in the passivation film 50 (see FIG. 1). The opening 50G can be formed by, for example, RIE using a mask (not illustrated). For example, in the formation of the opening 50G, an F-based gas is used as a reactive gas.

Next, a gate electrode 43 is formed on the passivation film 50 and the dielectric oxynitride film 31 so as to contact the dielectric oxynitride film 31 through the opening 50G (see FIG. 1). When the gate electrode 43 is formed, for example, a metal layer is formed by using a growth mask (not illustrated) having an opening in a region where the gate electrode 43 is to be formed, and then the growth mask is removed together with the metal layer (not illustrated) formed on the growth mask. That is, lift-off is performed.

Next, an opening 50S for the source and an opening 50D for the drain are formed in the passivation film 50 (see FIG. 1). The opening 50S and the opening 50D can be formed by, for example, RIE using a mask (not illustrated). For example, in the formation of the opening 50S and the opening 50D, an F-based gas is used as a reactive gas.

In this manner, the semiconductor device 1 can be manufactured.

The deposition apparatus used to nitride the dielectric oxide film 39 may be a low pressure chemical vapor deposition (LPCVD) apparatus or a rapid thermal annealing (RTA) apparatus. Further, the N source for nitriding the dielectric oxide film 39 may be ammonia (NH₃), dinitrogen monoxide (N₂O), or nitrogen monoxide (NO) gas.

In the semiconductor device 1 according to the embodiment, the surface of the nitride semiconductor layer 20 facing the dielectric oxide film 39, that is, the surface of the nitride semiconductor layer 20 facing the dielectric oxynitride film 31 after the nitridation has an N-polarity, and thus the distance between the channel region 26 and the source electrode 42S and the drain electrode 42D can be easily reduced, and a reduction in resistance can be easily achieved.

Further, the dielectric oxynitride film 31 functions as a gate insulating film. The dielectric oxynitride film 31 has a higher insulating property and a higher breakdown voltage than those of the dielectric oxide film 39. According to the present embodiment, gate leakage can be reduced.

Further, the first concentration of N atoms at the first point 61 in the dielectric oxynitride film 31 is higher than the second concentration of N atoms at the second point 62 in the dielectric oxynitride film 31. That is, the concentration of N atoms is higher at a point closer to the first surface 31A. Therefore, the affinity between the dielectric oxynitride film 31 and the nitride semiconductor layer 20 is high, and an interface state formed at the interface between the dielectric oxynitride film 31 and the nitride semiconductor layer 20 is reduced, and thus current collapse can be suppressed.

Further, when the concentration of N atoms in the dielectric oxynitride film 31 continuously changes with respect to the distance from the first surface 31A, the electric field applied to the dielectric oxynitride film 31 is gradually relaxed, and the breakdown voltage of the dielectric oxynitride film 31 can be improved.

The dielectric oxide film 39 includes at least one selected from the group consisting of hafnium, lanthanum, and zirconium, and thus the dielectric oxynitride film 31 can easily have a high relative dielectric constant. Further, the dielectric oxide film 39 includes at least one selected from the group consisting of silicon and aluminum, and thus the dielectric oxynitride film 31 can easily have a relative dielectric constant.

Although embodiments have been described in detail above, the present disclosure is not limited to the specific embodiments, and various modifications and changes can be made within the scope described in the claims.

What is claimed is:

1. A semiconductor device comprising:
a nitride semiconductor layer;
a dielectric oxynitride film provided on the nitride semiconductor layer and having a first surface facing the nitride semiconductor layer; and
a gate electrode provided on the dielectric oxynitride film, wherein
a surface of the nitride semiconductor layer facing the dielectric oxynitride film has a nitrogen polarity.

2. The semiconductor device according to claim 1, wherein a first concentration of nitrogen atoms at a first point in the dielectric oxynitride film is higher than a second concentration of nitrogen atoms at a second point in the dielectric oxynitride film, the first point being spaced apart from the first surface by a first distance, and the second point being spaced apart from the first surface by a second distance that is longer than the first distance.

3. The semiconductor device according to claim 2, wherein a concentration of nitrogen atoms in the dielectric oxynitride film continuously changes with respect to a distance from the first surface.

4. The semiconductor device according to claim 1, wherein the dielectric oxynitride film includes at least one selected from a group consisting of hafnium, lanthanum, and zirconium.

5. The semiconductor device according to claim 4, wherein the dielectric oxynitride film includes at least one selected from a group consisting of silicon and aluminum.

6. A method of manufacturing a semiconductor device, the method comprising:
forming, on a nitride semiconductor layer, a dielectric oxide film having a higher relative dielectric constant than a relative dielectric constant of silicon dioxide;
forming a dielectric oxynitride film by nitriding the dielectric oxide film; and
forming a gate electrode on the dielectric oxynitride film, wherein
a surface of the nitride semiconductor layer facing the dielectric oxide film has a nitrogen polarity.
